(19) United States
(12) Patent Application Publication
(10) Pub. No.: US 2008/0142799 A1
(43) Pub. Date: Jun. 19, 2008

(54) Semiconductor device having zener diode and method for manufacturing the same

(75) Inventor: Atsushi Kaneko, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/984,796

(22) Filed: Nov. 21, 2007

(30) Foreign Application Priority Data
Nov. 24, 2006 (JP) 317310/2006

(51) Int. Cl. H01L 27/06; H01L 21/8234

(52) U.S. Cl. 257/49; 438/237; 257/E27.016; 257/E21.621

(57) ABSTRACT

Disclosed herewith is a semiconductor device comprising a trench gate electrode and a zener diode, as well as a method for manufacturing the same. The trench gate electrode is formed in a semiconductor body and includes a first polycrystalline silicon layer doped with impurities of a first conductivity type at a first concentration. An extended gate electrode is elongated over the semiconductor body in contact with the trench gate electrode, and includes a second polycrystalline silicon layer doped with impurities of the first conductivity type at a second concentration that is lower than the first concentration. The zener diode is formed over the semiconductor body and includes a third polycrystalline silicon layer of a first conductivity type and a fourth polycrystalline silicon layer of a second conductivity type. The first polycrystalline silicon of the trench gate electrode is formed independently while the second polycrystalline silicon of the extended gate electrode and the third polycrystalline silicon of the zener diode are formed simultaneously, thereby the number of manufacturing processes is suppressed from increasing while the designing freedom of the zener diode is improved.

### CROSS-REFERENCE TO RELATED APPLICATIONS

This application is based upon, claims the benefit of priority of, and incorporates by reference the contents of Japanese Patent Application No. 2006-317310 filed on Nov. 24, 2006.

### BACKGROUND

1. Field of the Invention

The present invention relates to a semiconductor device and a method for manufacturing the same, more particularly to a semiconductor device including a zener diode and a method for manufacturing the same.

2. Description of Related Art

A transistor that employs a trench gate type MOSFET structure enables cells to be shrunken easily. It shows low on-resistance performance. On the other hand, such a transistor is required to form an extended gate electrode at the outermost periphery of each cell to pull out a trench gate electrode (mainly made of polycrystalline silicon) filled in a trench of a semiconductor body to the surface and to be connected to a gate pad provided over the semiconductor body.

Hereunder, there will be described a method for manufacturing a conventional semiconductor device with reference to FIGS. 6A through 10B. At first, a nitride layer 201 is formed on a semiconductor body 10 is then subjected to a thermal oxidation process to form a field oxide layer 202. Consequently, a foundation to be formed a zener diode and a surface gate electrode thereon is formed as shown in FIG. 6A. After this, the surface is etched with use of a photoresist mask (hereinafter, to be referred to as a “PR mask”) 203 to form a trench 204 (FIG. 6B). Then, the PR mask 203 is removed and a gate insulating layer 205 is formed in the trench (FIG. 6C).

After that, a non-doped polycrystalline silicon layer 206 is grown so as to fill the trench 204 (FIG. 7A). Then, a region in which a zener diode is to be formed is covered with a PR mask 207 and the portion is subjected to a heavy doping phosphor diffusion process so as to transform the non-doped polycrystalline silicon layer 206 into a heavily doped (1×10²⁰ cm⁻² or so) polycrystalline silicon layer 208 (FIG. 7B). After that, a portion where an extended gate electrode and a zener diode are to be formed is covered with a PR mask 209 and polycrystalline silicon layers 206 and 208 are removed partially. Consequently, a trench gate electrode 221 and an extended gate electrode 222 are formed (FIG. 7C).

Next, a PR mask 210 is formed and boron ions are implanted (by 1×10¹⁴ cm⁻² or so at 50 to 150 keV) into the non-doped polycrystalline silicon layer 206 in the portion where a zener diode is to be formed. Furthermore, the polycrystalline silicon layer 206 is subjected to a diffusion process for about 20 to 60 minutes at 1000 to 1100 degrees C. to form a P type polycrystalline silicon layer 211 (FIG. 8A). Then, a PR mask 212 is formed and arsenic ions (1×10¹⁶ cm⁻² or so at 30 to 70 keV) are implanted in part of the P type polycrystalline silicon layer 211. After removing the PR mask 212, the ion-implanted part is subjected to a diffusion process for about 20 to 60 minutes at 900 to 1000 degrees C to form an N type polycrystalline silicon layer 213 (FIG. 8B). Consequently, a zener diode 214 is obtained.

Next, boron ions (1×10¹² cm⁻² at 100 to 200 keV) are implanted into the object part and the object part is then subjected to a diffusion process for about 5 to 120 minutes at 950 to 1100 degrees C. to form a P type base region 215 in each cell (FIG. 8C). Then, arsenic ions (1×10¹⁵ to 10¹⁶ cm⁻² at 30 to 70 keV) are implanted into the object part with use of a PR mask 216, then the object part is subjected to a diffusion process for about 30 to 60 minutes at 850 to 1000 degrees C. to form an N⁺ type source region 217 (FIG. 9A). Then, the PR mask 218 is used to implant boron ions (1×10¹⁴ to 10¹⁶ cm⁻² at 30 to 70 KeV) into the object part, which is then diffused to form a heavily doped P⁺ type base region 219 (FIG. 9B). Consequently, a diffusion layer is formed in each cell. The order of the above processes might be changed according to the diffusion condition. In this embodiment, no PR mask is used for implanting impurity ions into the P type base region 215 while PR masks 216 and 218 are used for implanting impurity ions into the N⁺ type source region 217 and into the heavily doped P⁺ type base region 219 respectively.

Next, an interlayer insulating layer 220 is formed to cover the trench gate electrode 221, the zener diode 214, and the extended gate electrode 222 (FIG. 10A). After that, a source electrode 223 and a surface gate electrode 224 are formed (FIG. 10B). The surface gate electrode 224 includes a gate pad (not shown) and a wire for connecting the gate pad to the extended gate electrode 222. Consequently, a semiconductor device having a trench gate type MOSFET and a zener diode is obtained.

In prior to the above conventional technique, there have been disclosed Japanese Unexamined Patent Application Publication No. HEI 10 (1998)-12877, No. 2000-91344 (P2000-91344A), and No. 2003-264289 (P2003-264289A) (patent family member is U.S. Pat. No. 6,323,518 B1).

FIG. 11 shows a cross sectional view of such a zener diode formed in the semiconductor device shown in FIG. 10B for describing its operation. The zener diode 214 includes a source electrode 223 and a gate electrode 224 connected to both ends thereof. And when a predetermined voltage is applied between the source electrode 223 and the gate electrode 224, the zener diode 214 is driven, thereby the source electrode 223 and the gate electrode 224 are conducted electrically to each other. An arrow 301 denotes a current path formed at that time. The operation voltage of the zener diode 214 is set lower than the breakdown voltage of the gate insulating layer 302 to prevent the gate insulating layer 302 from overvoltage breakdown.

However, the present inventor has now discovered that the above conventional zener diode forming technique has been confronted with the following problems. The impurity concentration of the polycrystalline silicon layer 208 used to form the trench gate electrode 221 and the extended gate electrode 222 is much higher than that of the polycrystalline silicon layer 206 used to form the zener diode 214, so that it is required to form a PR mask 207 upon diffusing impurities in the polycrystalline silicon layer 208 in the process shown in FIG. 7B to protect the object layer from mixture of unnecessary impurities into the polycrystalline silicon layer 206. In other words, a photolithography process is required to form the PR mask 207 in the process of impurity diffusion in the polycrystalline silicon layer 208 used to form the trench gate electrode 221 and the extended gate electrode 222.

Furthermore, in order to keep the polycrystalline silicon layer used to form the zener diode at a light doping concentration, it is impossible to make a heavily doped polycrystalline silicon layer grow in the process shown in FIG. 7A. After the growth of the non-doped polycrystalline silicon layer 206, therefore, impurity diffusion is required to realize the necessary heavy doping.

Furthermore, as shown in FIG. 7A, the polycrystalline silicon growing condition (thickness, etc.) are set by taking consideration to the trench 204 filling property, etc. In other words, the polycrystalline silicon growing condition is optimized for forming the trench gate electrode 221, it is not necessarily optimized for forming the zener diodes. Consequently, the operation voltage and the zener diode operation resistance come to be limited upon designing. Forming of the zener diode thus comes to be difficult depending on the condition. If the depositing condition of the polycrystalline silicon layer 206 is limited by the trench filling condition such way, the freedom for designing the zener diode 214 also comes to be limited.

One solution may be that the zener diode and the trench gate electrode are formed separately. In this case, however, the manufacturing cost increases. Under such circumstances, the present inventor has thus sought a method for solving above mentioned problems, that is, solving the trade-off between improvement of the designing freedom of the zener diode and suppress of the manufacturing cost.

### SUMMARY

A semiconductor device, which is a first feature of the present invention, comprises a trench gate structure selectively formed in a semiconductor body, the trench gate structure having a trench gate electrode including a first polycrystalline silicon layer doped with impurities of a first conductivity type at a first concentration, the trench gate structure further having an extended gate electrode including a second polycrystalline silicon layer elongated over the semiconductor body in contact with the trench gate electrode and doped with impurities of the first conductivity type at a second concentration that is lower than the first concentration.

A method for manufacturing a semiconductor device, which is a second feature of the present invention, forms a trench gate electrode including a first polycrystalline silicon layer, and forms an extended gate electrode connected to the trench gate electrode and including a second polycrystalline silicon layer. The trench gate is provided in a semiconductor body, and the extended gate electrode is provided over the semiconductor body. The first polycrystalline silicon layer is doped with impurities of a first conductivity type at a first concentration, and the second polycrystalline silicon layer is doped with impurities of the first conductivity type at a second concentration that is lower than the first concentration.

In this semiconductor device, the first polycrystalline silicon layer that is heavily-doped and the second polycrystalline silicon layer that is lightly-doped or non-doped are formed separately. Further, a zener diode is formed with a third polycrystalline silicon layer of the first conductivity type and a fourth polycrystalline silicon layer of a second conductivity type. Typically, the second, third, and fourth polycrystalline silicon layers are deposited simultaneously. After that, the impurities of the first conductivity type at the second concentration that is lower than the first concentration are doped in the second and third polycrystalline silicon layers simultaneously. The impurities doped in the first and second polycrystalline silicon layer are selected separately, for example, phosphorous and arsenic ones. However, they may be the same. Typically, the concentration of the impurities doped in the first polycrystalline silicon layer is set higher so as to lower a resistance of the trench gate electrode while the concentration of the impurities doped in the second and third polycrystalline silicon layer is set lower so as to be determined by the operation voltage of the zener diode.

According to the present invention, therefore, it is possible to form the trench gate electrode independently with the extended gate electrode and the third polycrystalline silicon layer, thereby suppressing a number of manufacturing processes from increasing and improving the designing freedom of the zener diode.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1A is a cross sectional view of a semiconductor device in an embodiment of the present invention;

FIG. 1B is a top view of the semiconductor device in the embodiment of the present invention;

FIG. 2A is a diagram for showing a manufacturing process of the embodiment;

FIG. 2B is a diagram for showing another manufacturing process of the embodiment;

FIG. 2C is a diagram for showing still another manufacturing process of the embodiment;

FIG. 3A is a diagram for showing still another manufacturing process of the embodiment;

FIG. 3B is a diagram for showing still another manufacturing process of the embodiment;

FIG. 4A is a diagram for showing still another manufacturing process of the embodiment;

FIG. 4B is a diagram for showing still another manufacturing process of the embodiment;

FIG. 5 is a cross sectional view of a zener diode formed in the embodiment shown in each of FIGS. 1A and 1B for describing its operation;

FIG. 6A is a diagram for showing a manufacturing process of a conventional semiconductor device;

FIG. 6B is a diagram for showing another manufacturing process of the conventional semiconductor device;

FIG. 6C is a diagram for showing still another manufacturing process of the conventional semiconductor device;

FIG. 7A is a diagram for showing still another manufacturing process of the conventional semiconductor device;

FIG. 7B is a diagram for showing still another manufacturing process of the conventional semiconductor device;

FIG. 7C is a diagram for showing still another manufacturing process of the conventional semiconductor device;

FIG. 8A is a diagram for showing still another manufacturing process of the conventional semiconductor device;

FIG. 8B is a diagram for showing still another manufacturing process of the conventional semiconductor device;

FIG. 8C is a diagram for showing still another manufacturing process of the conventional semiconductor device;

FIG. 9A is a diagram for showing still another manufacturing process of the conventional semiconductor device;

FIG. 9B is a diagram for showing still another manufacturing process of the conventional semiconductor device;

FIG. 10A is a diagram for showing still another manufacturing process of the conventional semiconductor device;

FIG. 10B is a diagram for showing still another manufacturing process of the conventional semiconductor device; and

FIG. 11 is a cross sectional view of a zener diode formed in the conventional semiconductor device for describing its operation.

### DETAILED DESCRIPTION OF THE PREFERRED EMBODIMENTS

The present invention will now be described herein with reference to illustrative embodiments. Those skilled in the art will recognize that many alternative embodiments can be accomplished using the teachings of the present invention and that the present invention is not limited to the embodiments illustrated for explanatory purposes.

Hereunder, preferred embodiments of a semiconductor device and the method for manufacturing the same of the present invention will be described in detail with reference to the accompanying drawings. In those drawings, the same reference numerals will be used for the same elements, avoiding redundant description.

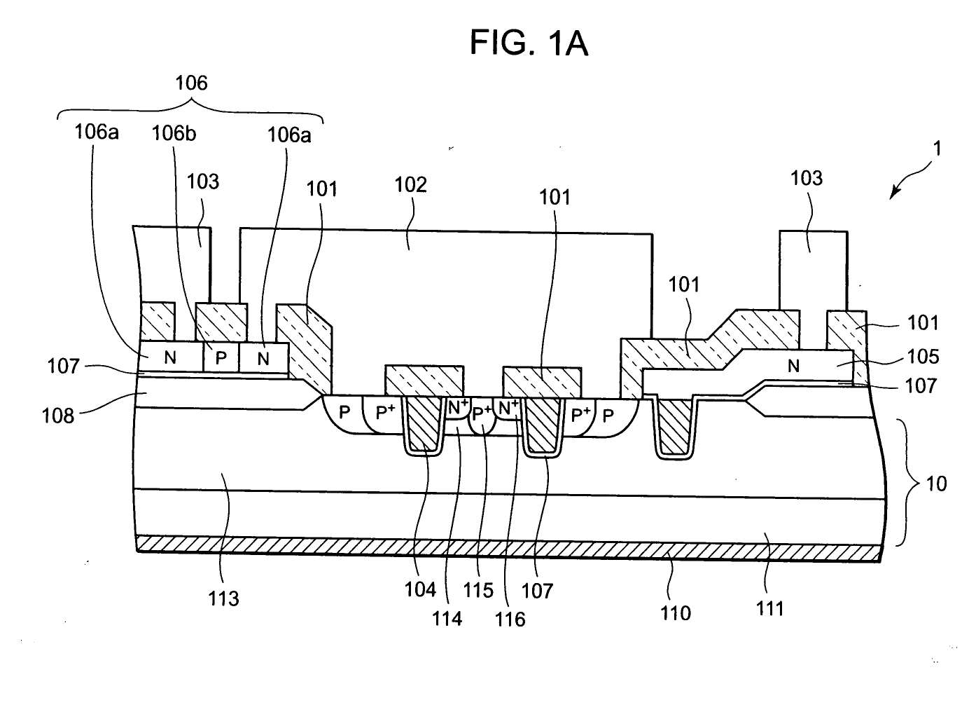

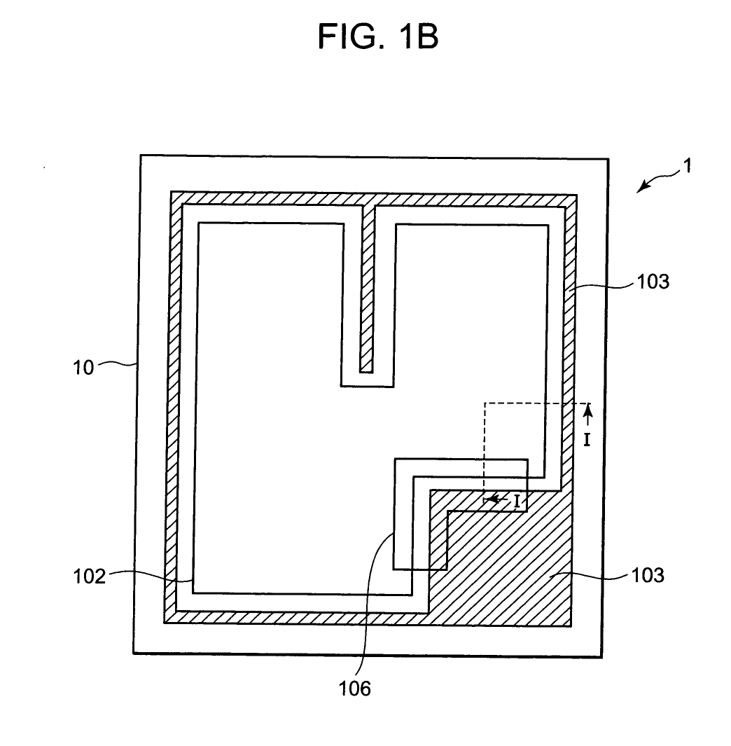

FIG. 1A and FIG. 1B show a cross sectional view and a top view of a semiconductor device 1 in an embodiment of the present invention. FIG. 1A shows a cross sectional view taken on broken line I-I of FIG. 1B. The semiconductor device 1 includes a vertical MOSFET (vertical Metal Oxide Semiconductor Field Effect Transistor) having a trench gate electrode 104 and a zener diode 106. The trench gate electrode 104 is formed in a trench formed in an N type epitaxial layer 113, with a gate insulating layer 107 intervening therebetween. The trench gate electrode 104 is connected to an extended gate electrode 105. The zener diode 106 includes a first region 106a of a first conductivity type and a second region 106b of a second conductivity type adjacent to the first region 106a. A semiconductor body 10 includes an N⁺ type silicon substrate 111 and an N type epitaxial layer 113 formed thereon, for example. The semiconductor body 10 functions as a drain region of the vertical MOSFET. A field oxide layer 108 is also formed on the semiconductor body 10. And on a back side of the semiconductor body 10 is formed a drain electrode 110.

First impurities of the first conductivity type are doped in the first polycrystalline silicon layer used to form the trench gate electrode 104. And second impurities of the first conductivity type are doped in the second polycrystalline silicon layer used to form the extended gate electrode 105. The first and second polycrystalline silicon layers are formed separately. The first and second impurities may be different or the same in type. The first region 106a of the zener diode 106 is formed with a third polycrystalline silicon layer of the first conductivity type and the second region 106b of the zener diode 106 is formed a fourth polycrystalline silicon layer of the second conductivity type. The second, third, and fourth polycrystalline silicon layers are formed by depositing a non-doped polycrystalline silicon layer and doping predetermined impurities into a predetermined region, so that they are approximately equal in thickness. The second impurities doped in the second polycrystalline silicon layer may be doped in the third polycrystalline silicon layer, simultaneously. Typically, the concentration of the first impurities is set higher so as to lower the resistance of the trench gate electrode 104 while the concentration of the second impurities is set lower than that of the first impurities, since the concentration of the second impurities is determined by an operation voltage of the zener diode 106. In this embodiment, the first and second conductivity types are N type and P type, but their types may be exchanged.

The second region 106b of the zener diode 106 is formed with the fourth polycrystalline silicon layer of the second conductivity type in which third impurities of the second conductivity type are doped. The second impurities of the first conductivity type and the third impurities of the second conductivity type may be doped in the second polycrystalline silicon layer used to form the extended gate electrode 105. In this embodiment, the first, second and third impurities are phosphorous, arsenic and boron. But only either phosphorous or arsenic impurities may be employed as both the first and second impurities.

Over the semiconductor body 10 is provided a surface gate electrode 103 connected to the extended gate electrode 105. The surface gate electrode 103 is connected electrically to the trench gate electrode 104 through the extended gate electrode 105. The surface gate electrode 103 includes a gate pad for connecting an external terminal (not shown), as well as a wiring for connecting the gate pad to the extended gate electrode 105 as shown in FIG. 1B. The surface gate electrode 103 is connected to both the extended gate electrode 105 and an one end (the first region 106a) of a zener diode 106.

In the semiconductor body 10 are formed a P type base region 114, a heavily doped P⁺ type base region 115, and an N⁺ type source region 116. The N⁺ type source region 116, the P type base region, the semiconductor body 10, the trench gate electrode 104 and the gate insulating layer 107 compose a vertical MOSFET. The N⁺ type source region 116 is adjacent to the trench gate electrode 104 with the gate insulating layer 107 therebetween. The second impurities of the first conductivity type may be doped in the N⁺ type source region 116. This N⁺ type source region 116 is connected to a source electrode 102 provided over the semiconductor body 10. The source electrode 102 is also connected to the other end (the first region 106a) of the zener diode 106. In other words, the source electrode 102 and the surface gate electrode 103 are connected to both poles of the zener diode 106 respectively.

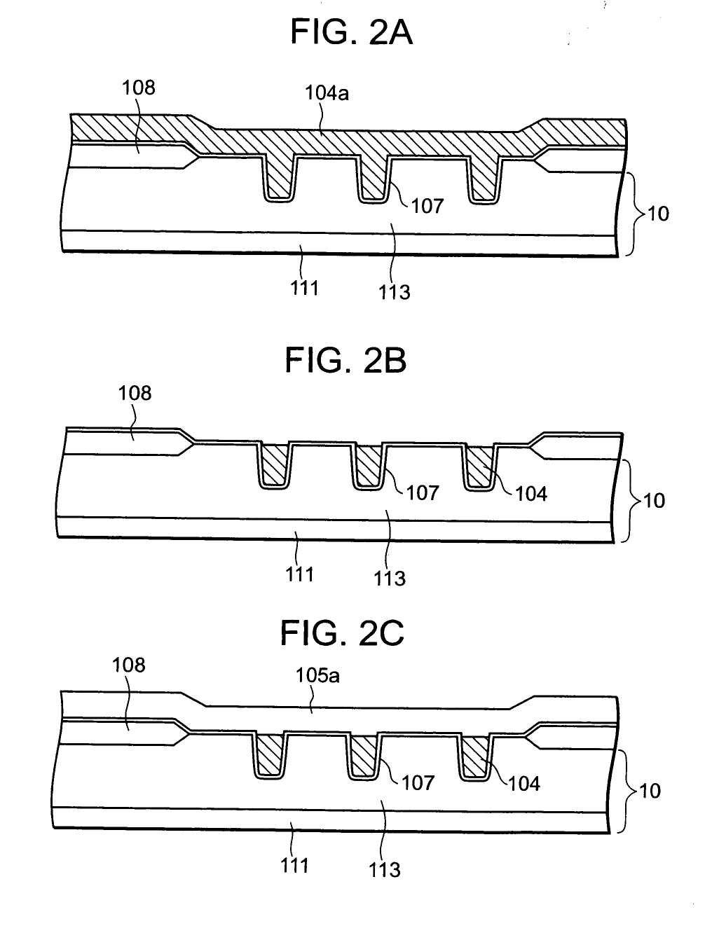

Next, there will be described a method for manufacturing the semiconductor device 1 with reference to FIGS. 2A through 5. In other words, this manufacturing method includes a process for forming a trench electrode 104 in the semiconductor body 10, a process for forming an extended gate electrode 105 over the semiconductor body 10 so as to be connected to the trench gate electrode 104, and a process for forming a zener diode 106 over the semiconductor body 10. The process for forming the trench gate electrode 104 is separated from any of the process for forming the extended gate electrode 105 and the process for forming the zener diode 106.

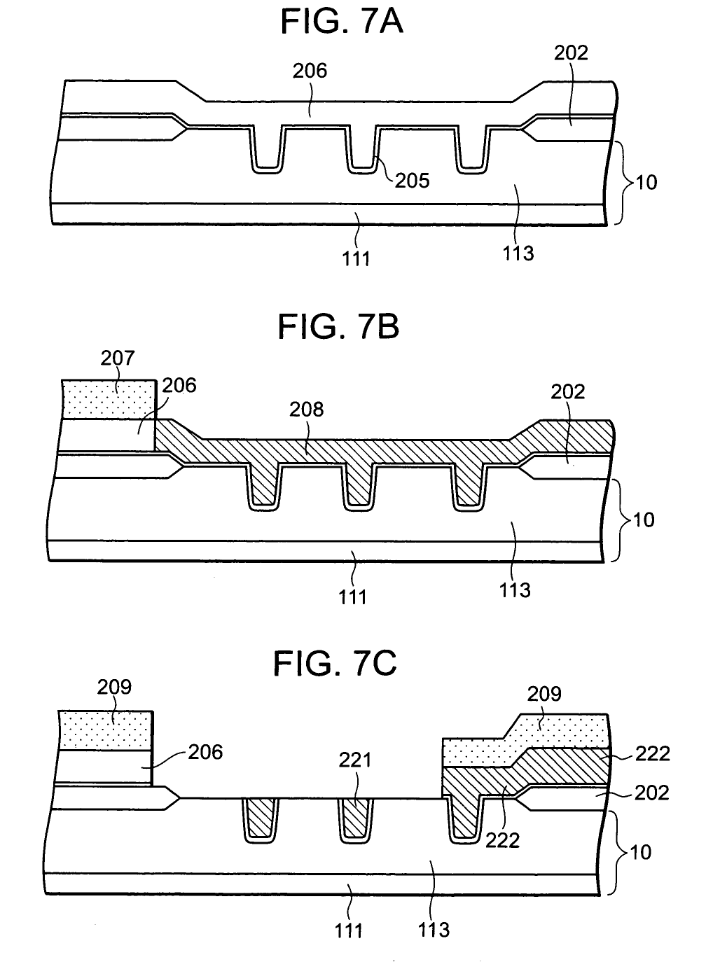

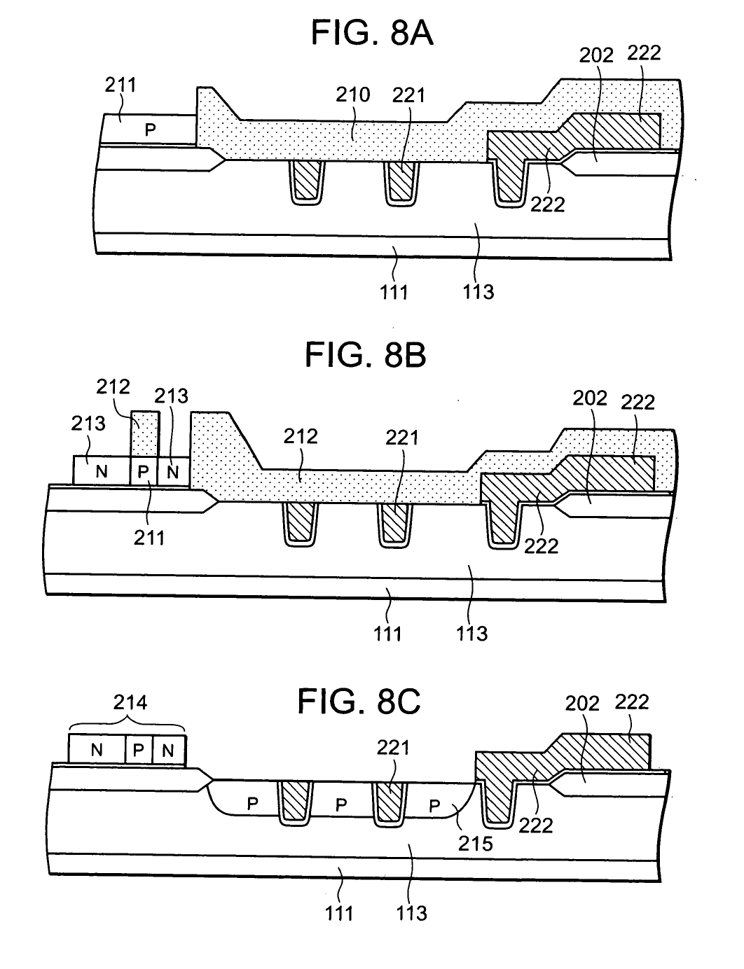

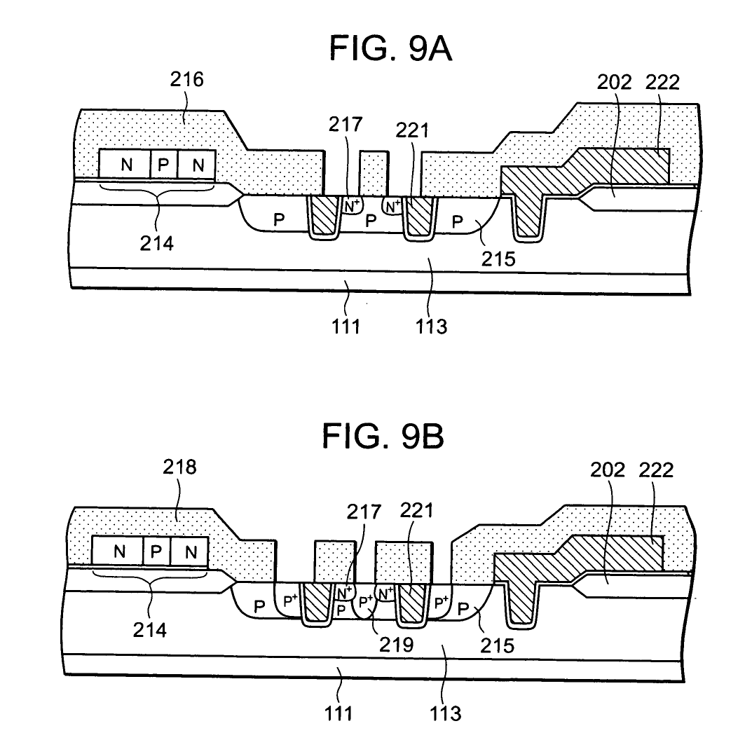

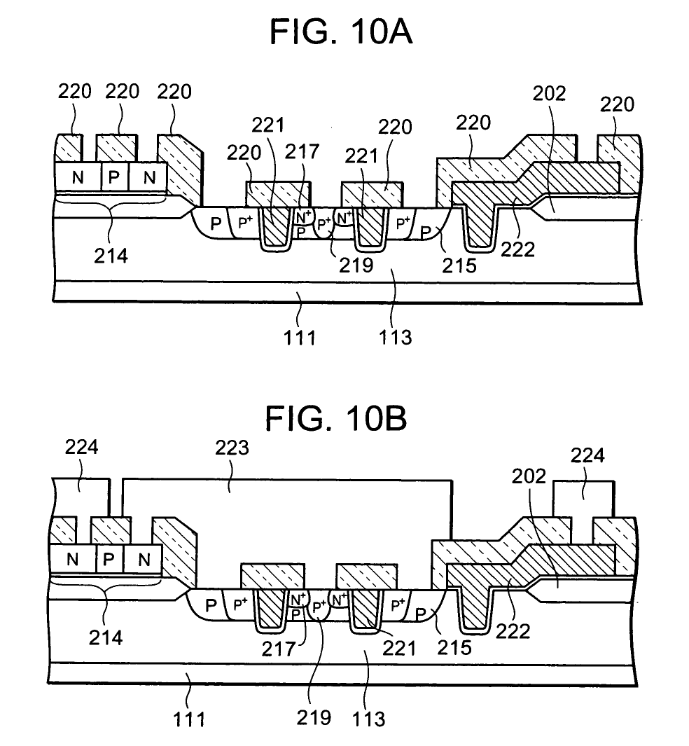

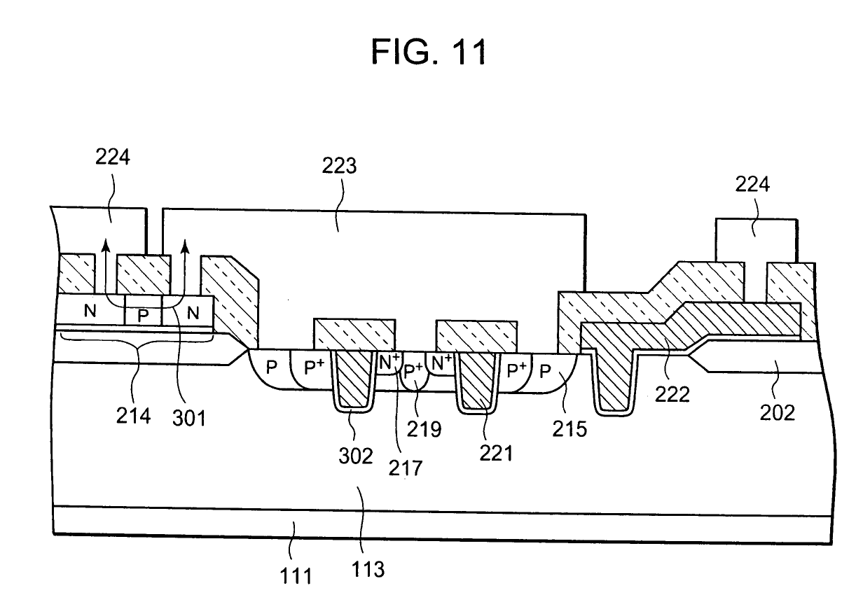

More concretely, at first, a field oxide layer 108, a trench, and a gate insulating layer 107 are formed in the semiconductor body 10. After that, a polycrystalline silicon layer 104a is grown all over the surface of the semiconductor body 10, then the layer 104a is subjected to a high concentration phosphorous diffusion process to form a first polycrystalline silicon layer (FIG. 2A). Here, unlike the conventional technique described with reference to FIG. 7B, no PR mask is used for the all-over high concentration phosphorous diffusion. This embodiment also makes it possible to deposit a polycrystalline silicon layer while doping impurities heavily into the layer so as to deposit a highly impurity concentrated polycrystalline silicon layer instead of high concentration impurity diffusion executed after depositing the polycrystalline silicon layer.

After that, the polycrystalline silicon layer 104a is subjected to etch-back without using any PR mask to remove the polycrystalline silicon layer 104a outside the trench. Consequently, a trench gate electrode 104 is formed in the trench (FIG. 2B). Then, a polycrystalline silicon layer 105a is grown, over the semiconductor body 10 (FIG. 2C). This polycrystalline silicon layer 105a should be a lightly-doped or non-doped polycrystalline silicon layer.

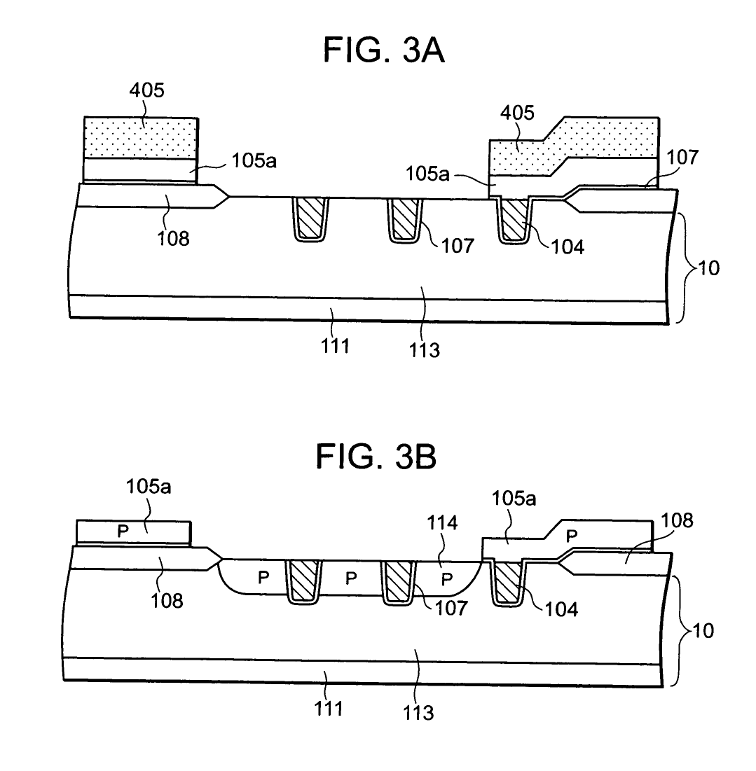

After that, the polycrystalline silicon layer 105a is removed from the surface except for the portions where the extended gate electrode 105 and the zener diode 106 are to be formed using a PR mask 405 (FIG. 3A). Such way, the trench gate electrode 104 is formed separately from any of the extended gate electrode 105 and the zener diode 106. Because the polycrystalline silicon layer 105a is kept lightly-doped or non-doped, the zener diode 106 forming is easy to optimize. This is why a designing freedom of the zener diode 106 is improved and a diffusion layer forming process of the MOSFET cell can be applied commonly to form the zener diode 106 and the extended gate electrode 105.

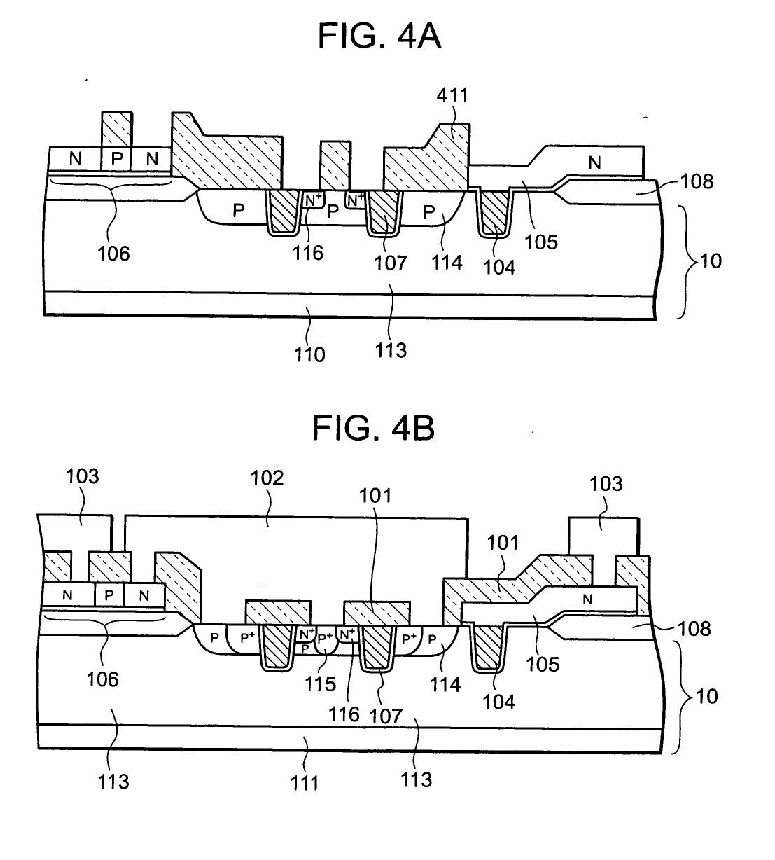

Actually, in FIG. 3B, after removing the PR mask 405 boron ions are implanted in the polycrystalline silicon layer 105a and the semiconductor body 10, thereby forming the second region 106b of the zener diode 106 and the P type base region 114 simultaneously. After that, in FIG. 4A, arsenic ions are implanted in the polycrystalline silicon layer 105a and the base region 114, thereby forming the first region 106a of the zener diode 106 and the N⁺ type source region 116 simultaneously. In this embodiment, boron ions and arsenic ions are implanted simultaneously in a region of the polycrystalline silicon layer 105a where the extended gate electrode 105 is to be formed.

The polycrystalline silicon layer 105a of the extended electrode 105 is transformed into a P type one by implanting boron ions therein, then transformed into an N type one by implanting arsenic ions therein. Consequently, an extended gate electrode 105 is formed. After that, a P⁺ type base region 115, an interlayer insulating layer 101, a source electrode 102, and a surface gate electrode 103 are formed (FIG. 4B). This completes forming of the semiconductor device 1 shown in FIG. 1A and FIG. 1B respectively.

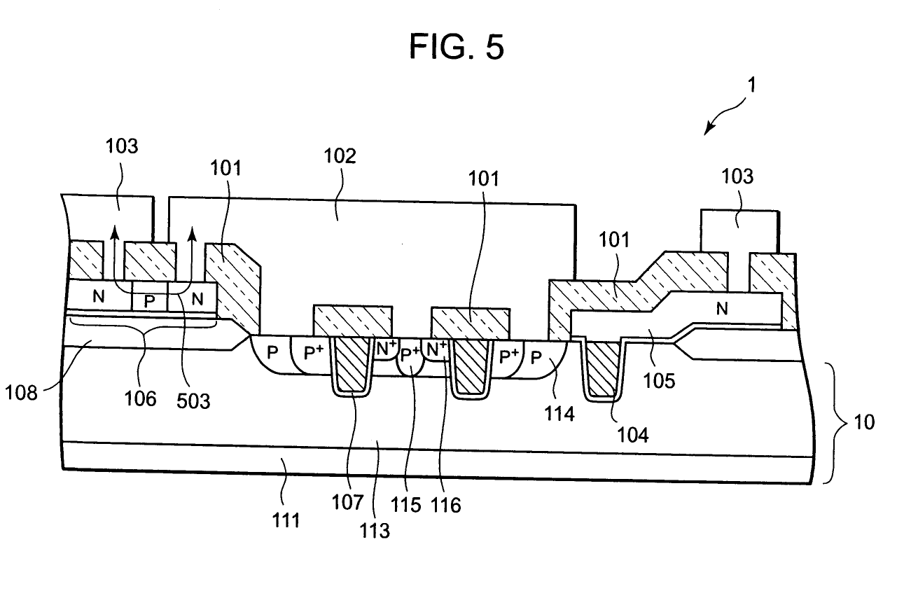

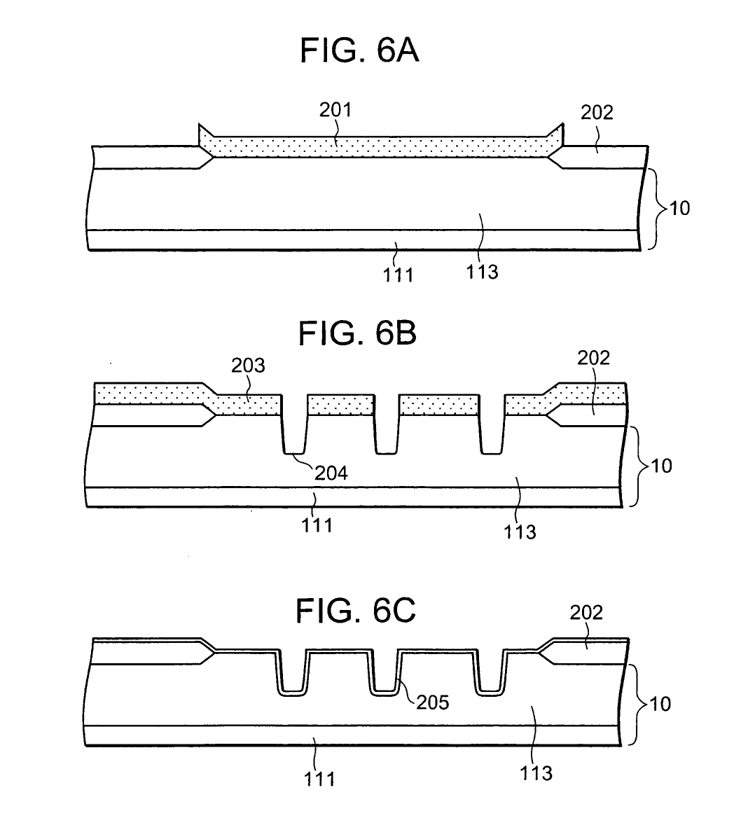

FIG. 5 shows a cross sectional view of a zener diode 106 formed in the semiconductor device 1 to describe its operation. If a voltage over the operation voltage of the diode is applied between the gate electrode 103 and the source electrode 102, a current is flown in the zener diode 106. At that time, the current flows as shown by an arrow 503. The operation voltage of the zener diode 106 is set under the breakdown voltage of the gate insulating layer 107, thereby the gate insulating layer 107 is prevented from overvoltage breakdown and accordingly the gate insulating layer 107 is protected.

The operation property of the zener diode 106 depends on the polycrystalline silicon growing condition, as well as the type and concentration of the diffused impurities in the zener diode 106. Consequently, upon forming the zener diode 106, it is required to secure the optimal operation performance with respect to the breakdown voltage of the gate insulating layer 107. If the gate insulating layer 107 is a thermal oxide layer, its breakdown voltage is about 20 V to 40 V at a thickness of 20 nm to 50 nm. The operation voltage of the zener diode 106 is required to be under the above described breakdown voltage and over a gate applied voltage applied to the gate electrode 104 at a time of normal device operation.

The extended gate electrode 105 enables the electrical connection between the trench gate electrode 104 and the surface gate electrode 103. Consequently, it is easy to pull out the gate electrode from the trench gate electrode 104 even when the trench gate electrode 104 is further fined. In this embodiment, as shown in FIGS. 2A through 2C, the polycrystalline silicon layer 104a (first polycrystalline silicon layer) for the trench gate electrode 104 is formed with heavily doped impurities, then the polycrystalline silicon layer 105a with lightly doped or non-doped impurities for both the extended gate electrode 105 and for the zener diode 106 are deposited, then predetermined impurities are doped into the predetermined region, thereby forming the impurities doped polycrystalline silicon layer 105a (second polycrystalline silicon layer) for the extended gate electrode 105 and the first region 106a (third polycrystalline silicon) of the zener diode 106 respectively.

In this embodiment, the deposition of the first polycrystalline silicon layer and doping of impurities into the trench gate electrode 104 are made separately from other polycrystalline silicon layers. Consequently, the resistance of the trench gate electrode 104 is lowered without affecting other polycrystalline silicon layers. In addition, because the third polycrystalline silicon layer for the first region 106a can be formed so as to optimize the operation performance of the zener diode 106 and both the second and third polycrystalline silicon layers can be deposited, patterned, and doped impurities simultaneously, the number of manufacturing processes is reduced. Although phosphorous and arsenic impurities are used as the first and second impurities respectively in this embodiment, the type of the impurities may be either of them. At least, the concentration of the first impurities to be doped into the first polycrystalline silicon layer 104a, as well as the second impurities to be doped into the second and third polycrystalline silicon layers can be optimized respectively, so that the zener diode 106 designing freedom can be much improved.

No photolithographic process is required from the deposition of the polycrystalline silicon layer 104a (FIG. 2A) up to the deposition of the polycrystalline silicon layer 105a (FIG. 2C). And as shown in FIG. 4A, the number of processes can further be reduced by doping the second impurities of the first conductivity type not only into the extended gate electrode 105 and the first region 106a of the zener diode 106 but also into the N⁺ type source region 116. Furthermore, as shown in FIG. 3B, the number of manufacturing processes can further be reduced by doping the third impurities of the second conductivity type not only into the polycrystalline silicon layer 105a but also into the P type base region 114.

According to this embodiment, therefore, it is possible to lower the impurity concentration of the extended gate electrode 105 more than that of any of the conventional techniques. Thus the resistance value of the electrode 105 can be increased, thereby the electrode 105 can be used effectively as a gate protection resistor. If an overvoltage is applied from external to the surface gate electrode 103 connected to the first region 106a of the zener diode 106, the resistance-increased extended gate electrode 105 can absorb the overvoltage, so that the gate insulating layer 107 can be further protected from insulation breakdown. On the other hand, the trench gate electrode 104 of the vertical MOSFET can be subjected to impurity diffusion separately from the extended gate electrode 105. Thus the gate resistance in each cell is lowered, thereby the gate voltage variation among cells is prevented and the electrical property is improved.

As described above, in this embodiment, the trench gate electrode 104 is formed separately from the extended gate electrode 105. And the trench gate electrode 104 is also formed separately from the zener diode 106. Consequently, it is possible to form the extended gate electrode 105 and the zener diode 106 simultaneously. This is why the present invention can realize a semiconductor device and a method for manufacturing the same so as to suppress the number of manufacturing processes from increasing and improve the designing freedom of the zener diode.

Although the present invention has been described above in conjunction with several preferred embodiments thereof, it will be appreciated by those skilled in the art that those embodiments are provided solely for illustrating the invention, and should not be relied upon to construct the appended claims in a limiting sense.

What is claimed is:

1. A semiconductor device, comprising:
a trench gate structure selectively formed in a semiconductor body, the trench gate structure having a trench gate electrode including a first polycrystalline silicon layer doped with impurities of a first conductivity type at a first concentration, the trench gate structure further having an extended gate electrode including a second polycrystalline silicon layer elongated over the semiconductor body in contact with the trench gate electrode and doped with impurities of the first conductivity type at a second concentration that is lower than the first concentration.

2. The semiconductor device according to claim 1, wherein the impurities doped in the first polycrystalline silicon layer are different from the impurities doped in the second polycrystalline silicon layer.

3. The semiconductor device according to claim 2, wherein the impurities doped in the first polycrystalline silicon layer are phosphorous impurities and the impurities doped in the second polycrystalline silicon layer are arsenic impurities.

4. The semiconductor device according to claim 1, further comprises a zener diode provided over the semiconductor body and having at least a third polycrystalline silicon layer of the first conductivity type and a fourth polycrystalline silicon layer of a second conductivity type,
wherein the impurities doped in the second polycrystalline silicon layer is doped in the third polycrystalline silicon layer.

5. The semiconductor device according to claim 4, wherein the second and third polycrystalline silicon layers are approximately equal in thickness.

6. The semiconductor device according to claim 4, wherein the second and fourth polycrystalline silicon layers include same impurities of the second conductivity type.

7. The semiconductor device according to claim 6, further comprises a base region of the second conductivity type,
wherein the impurities doped in the second and fourth polycrystalline silicon layers are doped in the base region.

8. The semiconductor device according to claim 7, wherein the impurities of the second conductivity type are boron impurities.

9. The semiconductor device according to claim 1, further comprises a surface gate electrode provided over the semiconductor body and connected to the extended gate electrode.

10. The semiconductor device according to claim 9, wherein the surface gate electrode is connected to both the extended gate electrode and an one end of the zener diode.

11. The semiconductor device according to claim 7, further comprises a source region of the first conductivity type provided in the base region,
wherein the impurities of the first conductivity type doped in the second polycrystalline silicon are doped in the source region.

12. A method for manufacturing a semiconductor device, comprising the steps of:
forming a trench gate electrode including a first polycrystalline silicon layer, the trench gate being provided in a semiconductor body; and
forming an extended gate electrode connected to the trench gate electrode and including a second polycrystalline silicon layer, the extended gate electrode being provided over the semiconductor body,
wherein the first polycrystalline silicon layer is doped with impurities of a first conductivity type at a first concentration, and
wherein the second polycrystalline silicon layer is doped with impurities of the first conductivity type at a second concentration that is lower than the first concentration.

13. The method according to claim 12, wherein forming of the first polycrystalline silicon layer and doping of the first impurities in the first polycrystalline silicon layer are made simultaneously.

14. The method according to claim 12, further comprises forming a zener diode including at least a third polycrystalline silicon layer and a fourth polycrystalline silicon layer, the zener diode being provided over the semiconductor body,
wherein the second, third, and fourth polycrystalline silicon layers are deposited simultaneously, and
wherein doping of the impurities of the first conductivity type at the second concentration is also made in the third polycrystalline silicon layer simultaneously.

15. The method according to claim 14, wherein the trench gate electrode is formed in prior to any of the forming the extended gate electrode and the forming the zener diode.

16. The method according to claim 14,
wherein the forming the zener diode further includes doping impurities of the second conductivity type in the fourth polycrystalline silicon layer, and
wherein doping of the impurities of the second conductivity type is also made in the second polycrystalline silicon layer simultaneously.

17. The method according to claim 16, wherein the impurities of the second conductivity type are also doped in the semiconductor body simultaneously, thereby forming a base region of the second conductivity type.

18. The method according to claim 12, further comprises forming a surface gate electrode connected to the extended gate electrode over the semiconductor body.

19. The method according to claim 18, wherein the forming the surface gate electrode further includes connecting the extended gate electrode to an one end of the zener diode through the surface gate electrode.

20. The method according to claim 17, wherein doping of the second impurities is made in the base region simultaneously, thereby forming a source region of the first conductivity type.
